(19) United States
(12) Patent Application Publication
(10) Pub. No.: US 2026/0353779 A1
(43) Pub. Date: Nov. 5, 2026

(54) GATE STRUCTURES FOR MULTI-GATE DEVICES

(71) Applicant: Taiwan Semiconductor Manufacturing Company, Ltd., Hsinchu (TW)

(72) Inventors: Yung-Hsiang Chan, Taichung (TW); Yao-Teng Chuang, Hsinchu (TW); Chih-Yu Hsu, Hsinchu County (TW); Kuo-Feng Yu, Hsinchu County (TW)

(21) Appl. No.: 19/274,073

(22) Filed: Jul. 18, 2025

Related U.S. Application Data
(60) Provisional application No. 63/797,562, filed on Apr. 30, 2025.

(51) Int. Cl. H10D 84/83; H10D 30/00; H10D 30/01; H10D 62/10; H10D 62/13; H10D 64/68; H10D 84/01

(52) U.S. Cl. CPC H10D 84/832; H10D 30/0191; H10D 30/502; H10D 62/102; H10D 62/121; H10D 62/151; H10D 64/685; H10D 64/691; H10D 64/693; H10D 84/0135; H10D 84/0144; H10D 84/8314

(57) ABSTRACT

A method for forming a gate structure according to the present disclosure includes providing a structure that includes a substrate, first nanostructures over a first region of the substrate, and second of nanostructures over a second region of the substrate, depositing a gate dielectric layer over the first nanostructures and the second nanostructures, depositing a first work function metal layer over the first nanostructures and the second nanostructures, depositing a diffusion blocking layer over the first work function metal layer, selectively removing the diffusion blocking layer and the first work function metal layer from the first nanostructures over the first region, depositing a second work function metal layer over the first nanostructures and the second nanostructures, and depositing a metal fill layer over the second work function metal layer.

### PRIORITY DATA

This application claims priority to U.S. Provisional Patent Application No. 63/797,562, filed on Apr. 30, 2025, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors (both also referred to as non-planar transistors) are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). Compared to planar transistors, such configuration provides better control of the channel and drastically reduces SCEs (in particular, by reducing sub-threshold leakage (i.e., coupling between a source and a drain of the FinFET in the “off” state)). A GAA transistor has a gate structure that can extend, partially or fully, around a channel region to provide access to the channel region on two or more sides. Due to this configuration, a GAA transistor may also be referred to as a surrounding-gate transistor (SGT) or a multi-bridge-channel (MBC) transistor. The channel region of the GAA transistor may be formed from nanowires, nanosheets, other nanostructures, and/or other suitable structures. These shapes of the channel region also give a GAA transistor different names. For example, a GAA transistor with nanosheet channel regions may be referred to as a nanosheet transistor.

In order to meet improved power consumption and other design needs, multi-gate transistors with different threshold voltages are desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a schematic flow of selectively introducing a dipole dopant into a device region, according to various aspects of the present disclosure.

FIG. 2 illustrates dopant concentration gradients in an interfacial layer and gate dielectric layer when a dipole dopant is selectively introduced using the schematic flow in FIG. 1.

FIG. 3 is a flowchart illustrating a method of forming a semiconductor device according to various aspects of the present disclosure.

FIGS. 4-22 illustrate fragmentary cross-sectional views of a first area and a second area of a precursor structure at various stages of fabrication in accordance with the method in FIG. 1.

FIG. 23 illustrates an alternative semiconductor structure when the method in FIG. 3 is implemented to form a fin-type field effect transistor (FinFET), according to various aspects of the present disclosure.

FIGS. 24-26 illustrates a schematic flow of selectively introducing a dipole dopant into more than two device regions, according to various aspects of the present disclosure.

FIG. 27 illustrates semiconductor devices in more than two device regions, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/–10 % of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/–15 % by one of ordinary skill in the art.

A GAA transistor has a gate structure that extends, partially or fully, around a channel region to provide access to the channel region on two or more sides. A channel region of a GAA transistor may include multiple sheet-like or wire-like nano-size channel members that are stacked one over another or placed side by side. In order to meet improved power consumption and other design needs, multi-gate transistors with different threshold voltages are desired. One way to fabricate multi-threshold devices is by introducing different amount of dipole dopant into different device regions. However, the selective introduction of dipole dopant can be challenging. For example, dipole dopant may find its way into areas that are supposed to be dopant-free and the dipole drive-in process may introduce additional variables. When this happens, high minimum operating voltage and high gate leakage current may be resulted due to heavy dry ion bombardment damage, high nitrogen incorporation, and dipole-high-k dielectrics intermixing.

The present disclosure relates to formation of multi-gate transistors with different threshold voltages. According to some embodiments, a barrier layer is formed on a dipole-free area. A dipole dopant source layer is then formed on a gate dielectric layer in dipole drive-in area and the barrier layer in the dipole-free area. Thereafter, a dipole drive-in process is performed. Due to the presence of the barrier layer, the concentration of the dipole dopant in the gate dielectric layer in the dipole drive-in area is greater than the concentration of the dipole dopant in the gate dielectric layer in the dipole-free area. Additionally, the nitrogen concentration in the gate dielectric layer in dipole drive-area is greater than the nitrogen concentration in the gate dielectric layer in dipole-free area. Processes of the present disclosure provide benefits, which include reduced minimum operating voltage and reduced gate leakage current.

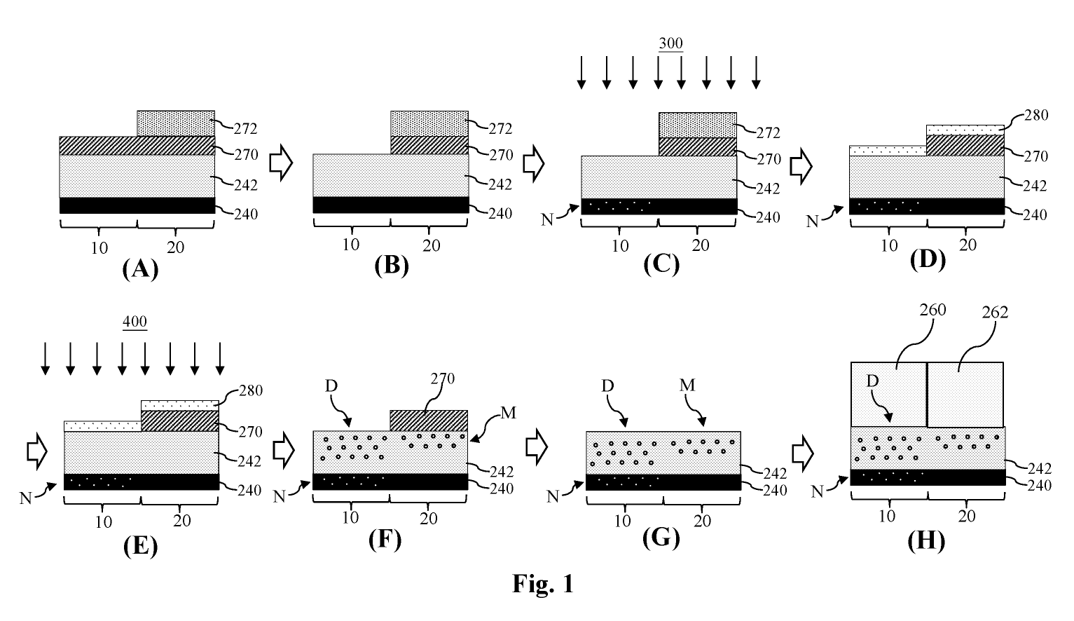

FIG. 1 illustrates a schematic flow of selectively introducing a dipole dopant into a device region. Instead of looking at multi-gate transistors as whole, FIG. 1 focuses on an interfacial layer 240 and a gate dielectric layer 242 and how various layers interact with them. FIG. 1 schematically illustrates stages (A), (B), (C), (D), (E), (F), (G), and (H). At stage (A), a barrier layer 270 is globally deposited over the gate dielectric layer 242 and the interfacial layer 240. In some embodiments, the interfacial layer 240 may include silicon oxide or hafnium silicate and the gate dielectric layer 242 may include hafnium oxide or other high-k dielectric material. According to the present disclosure, the barrier layer 270 is a dielectric layer that is capable to slow down diffusion of dipole dopant. For example, the barrier layer 270 may include titanium oxide (TiO), titanium nitride (TiN), titanium tungsten nitride (TiWN), tungsten carbonitride (WCN), tennessine nitride (TsN), aluminum nitride (AlN), or titanium aluminum carbide (TiAlC). In one, the barrier layer 270 includes aluminum oxide or aluminum nitride. In order to pattern the barrier layer 270, a mask layer 272 is deposited on the barrier layer 270 and is patterned. In the depicted embodiments, the mask layer 272 is a photoresist layer and is patterned using photolithography techniques. At stage (A) in FIG. 1, the patterned mask layer 272 covers a second region 20 while a first region 10 is not covered by or vertically overlapped by the patterned mask layer 272. At stage (B) in FIG. 1, the barrier layer 270 over the first region 10 is selectively removed using the patterned mask layer 272 as an etch mask. The etch process at stage (B) may be a dry etch that implements a fluorine-containing gas, a chlorine-containing gas, or oxygen. At stage (B), the barrier layer 270 is selectively removed from over the first region 10.

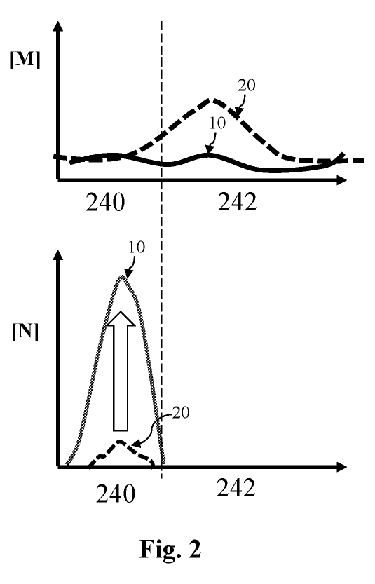

After the selective removal of the barrier layer 270, the patterned mask layer 272 is removed using an ashing process 300 at stage (C). In some embodiments, the ashing process 300 implements nitrogen (N₂) and hydrogen (H₂). Due to the lack of the mask layer 272 and the barrier layer 270, the ashing process 300 may introduce nitrogen into the interfacial layer 240 as indicated by “N” in FIG. 1. Reference is briefly made to FIG. 2. The bottom diagram in FIG. 2 illustrates a representative nitrogen concentration [N] in the interfacial layer 240 and the gate dielectric layer 242 in the first region 10 and the second region 20. In FIG. 2, the lack of the barrier layer 270 over the first region 10 allows more nitrogen to be introduced into the interfacial layer 240 over the first region 10 during the ashing process 300. Because the dipole dopant layer 280 is not deposited yet, the intermixing of the dipole dopant and nitrogen over the first region 10 can be avoided. The intermixing of the dipole dopant and the nitrogen may lead to increased leakage. Contrarily, the patterned mask layer 272 and the barrier layer 270 significantly reduce nitrogen introduction into the interfacial layer 240 over the second region 20. Referring still to FIG. 1, a dipole dopant layer 280 (or a dipole dopant source layer 280) is deposited over the first region 10 and the second region 20 at stage (D). Over the first region 10, the dipole dopant layer 280 is deposited directly on the gate dielectric layer 242. Over the second region 20, the dipole dopant layer 280 is spaced apart from the gate dielectric layer 242 by the barrier layer 270. The dipole dopant layer 280 may include n-dipole dopant or p-dipole dopant. Example n-dipole dopants may include lanthanum (La), yttrium (Y), lutetium (Lu), strontium (Sr), erbium (Er), or magnesium (Mg). Example p-dipole dopants may include titanium (Ti), aluminum (Al), or niobium (Nb). The dipole dopant layer 280 may be nitrides or oxides of these example dipole dopant species. For example, when the desired n-dipole dopant is lanthanum (La), the dipole dopant layer 280 may be lanthanum oxide or lanthanum nitride. When the desired n-dipole dopant is magnesium (Mg), the dipole dopant layer 280 may be magnesium oxide or magnesium nitride. When the desired p-dipole dopant is aluminum, the dipole dopant layer 280 may be aluminum oxide or aluminum nitride. In one embodiment, the dipole dopant layer 280 includes lanthanum oxide or lanthanum nitride.

At stage (E), a dipole drive-in process 400 is performed to facilitate and accelerate diffusion of the dipole dopant into the gate dielectric layer. In some implementation, the dipole drive-in process 400 may include an anneal process having an anneal temperature or a process temperature between about 500 ℃ and about 800 ℃. As shown in FIG. 1, the dipole drive-in process 400 not only drives a dipole dopant (D) into the gate dielectric layer 242 over the first region 10 but also drives metal dopant (M) from the barrier layer 270 into the gate dielectric layer 242 over the second region 20 at stage (F). Reference is made to FIG. 2. The top diagram in FIG. 2 illustrates a representative metal dopant concentration [M] in the interfacial layer 240 and the gate dielectric layer 242 in the first region 10 and the second region 20. Because the barrier layer 270 is disposed over the second region 20 during the dipole drive-in process 400, the metal dopant concentration [M] in the gate dielectric layer 242 over the second region 20 is significantly higher than that over the first region 10. When the barrier layer 270 includes aluminum oxide, the metal dopant M is aluminum (Al). After the dipole drive-in process 400, the dipole dopant layer 280 is selectively removed, exposing the gate dielectric layer 242 over the first region 10 and the barrier layer 270 over the second region 20. At stage (G), the barrier layer 270 over the second region 20 is also removed. Finally, at stage (H), a first gate electrode 260 is formed over the first region 10 and a second gate electrode 262 is formed over the second region 20. The first gate electrode 260 and the second gate electrode 262 may have similar compositions. Each of them may include at least one work function layer, an optional diffusion barrier layer, and a metal fill. Because the work function layer includes the element titanium, it can be said that the first gate electrode 260 and the second gate electrode 262 include a titanium-based material.

Based on the foregoing description and the illustration in FIG. 2, methods of the present disclosure allow more dipole dopant to be introduced in the interfacial layer 240 in first region 10, reduce gate leakage, and more metal dopant to be introduced in the interfacial layer in the second region 20. This allows the transistors formed over the first region 10 and the second region 20 to have different threshold voltages and the leakage current due to intermixing of the dipole dopant and nitrogen be reduced. In an embodiment where the dipole dopant from the dipole dopant layer 280 is lanthanum and the metal dopant from the barrier layer 270 is aluminum, the dipole dopant may lower the threshold voltage for n-type transistors and the metal dopant may increase the threshold voltage for n-type transistors. The effect on p-type transistors may be completely opposite. In an embodiment where the dipole dopant from the dipole dopant layer 280 is lanthanum and the metal dopant from the barrier layer 270 is aluminum, the dipole dopant may increase the threshold voltage for p-type transistors and the metal dopant may lower the threshold voltage for p-type transistors.

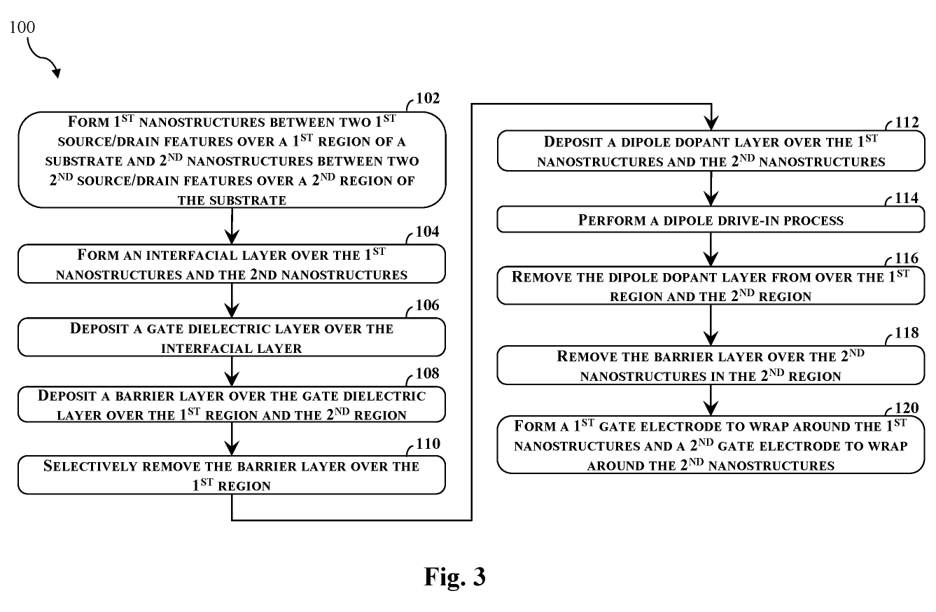

FIG. 3 is a flowchart illustrating a method 100 for forming a semiconductor structure for a multi-gate device according to various aspects of the present disclosure. Method 100 is merely an example and is not intended to limit the present disclosure to what is explicitly illustrated in method 100. Additional steps may be provided before, during and after method 100 and some steps described can be replaced, eliminated, or moved around for additional embodiments of the method. Not all steps are described herein in detail for reasons of simplicity. Method 100 is described below in conjunction with FIGS. 2-20, which are fragmentary cross-sectional views of a precursor structure 200 at different stages of fabrication according to embodiments of method 100. Because the precursor structure 200 will be fabricated into a semiconductor device 200 or a semiconductor structure 200 upon conclusion of the fabrication processes, the precursor structure 200 may be referred to as the semiconductor device 200 or the semiconductor structure 200 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

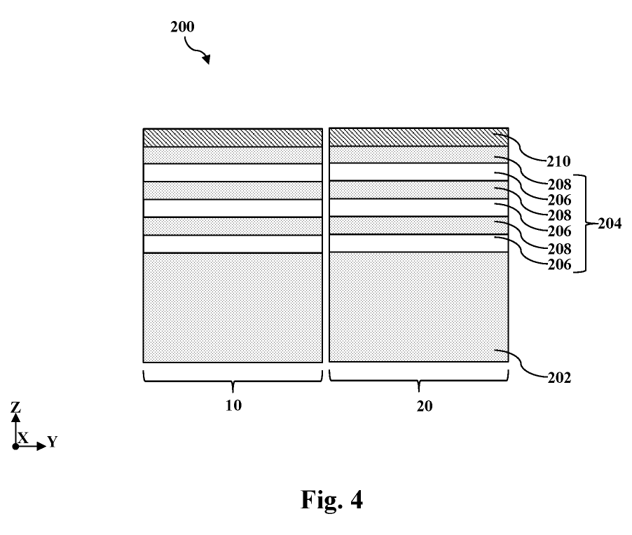

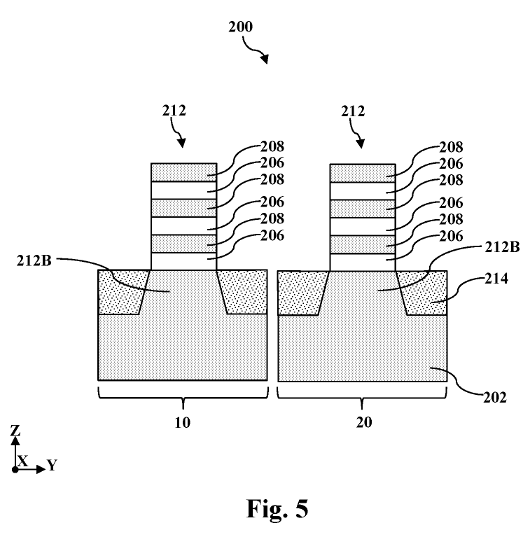

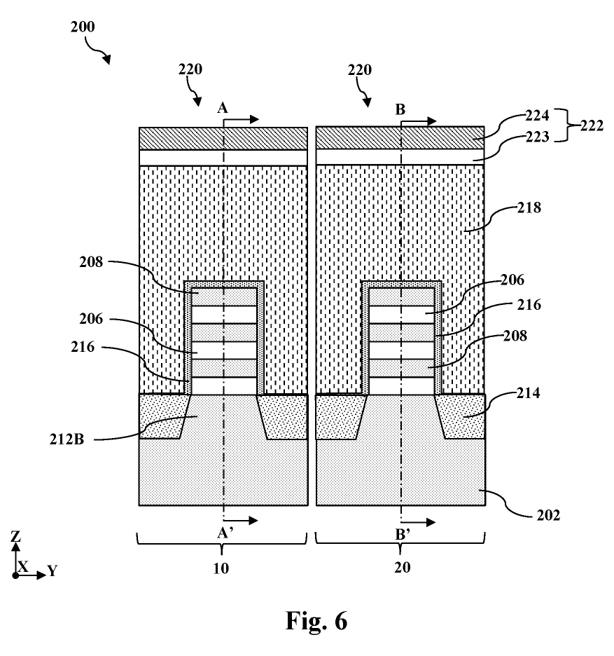

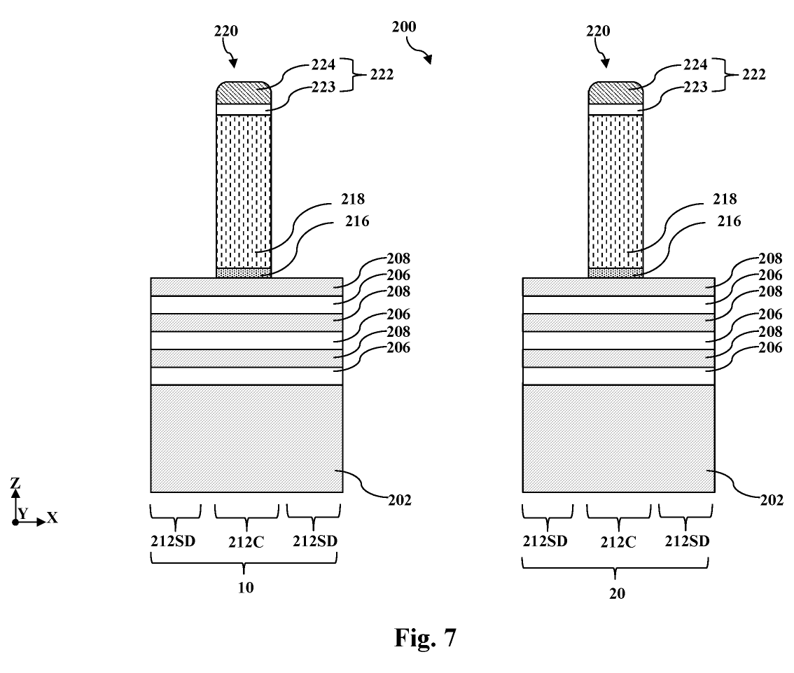

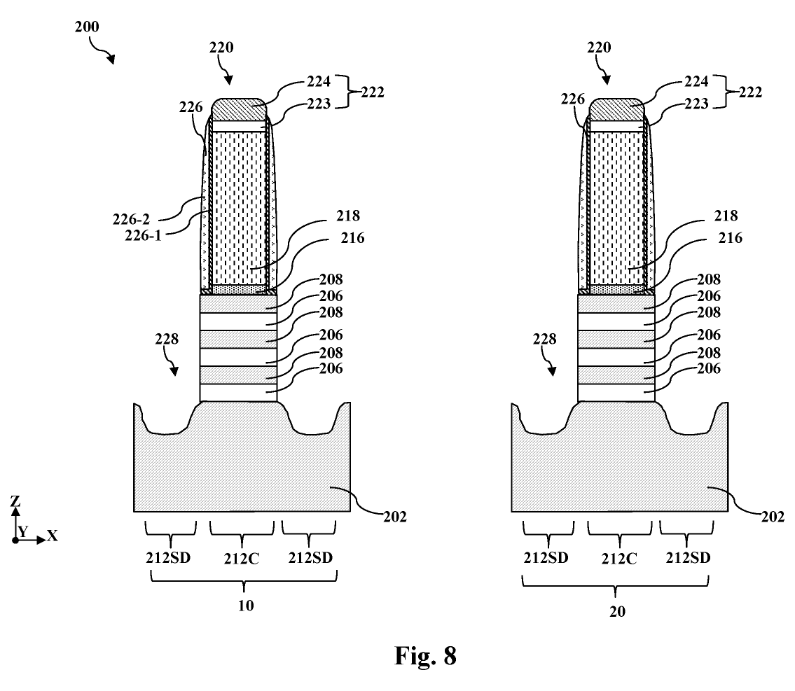

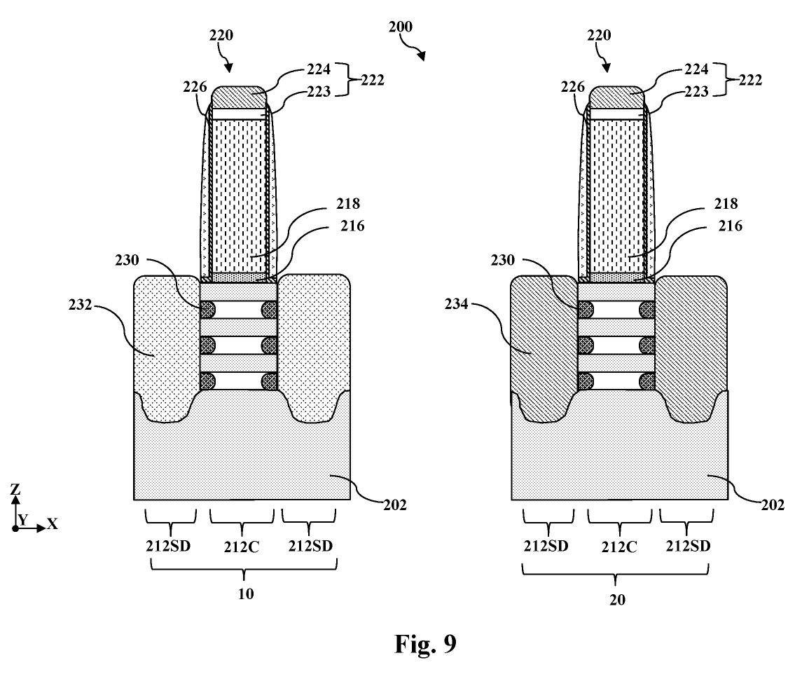

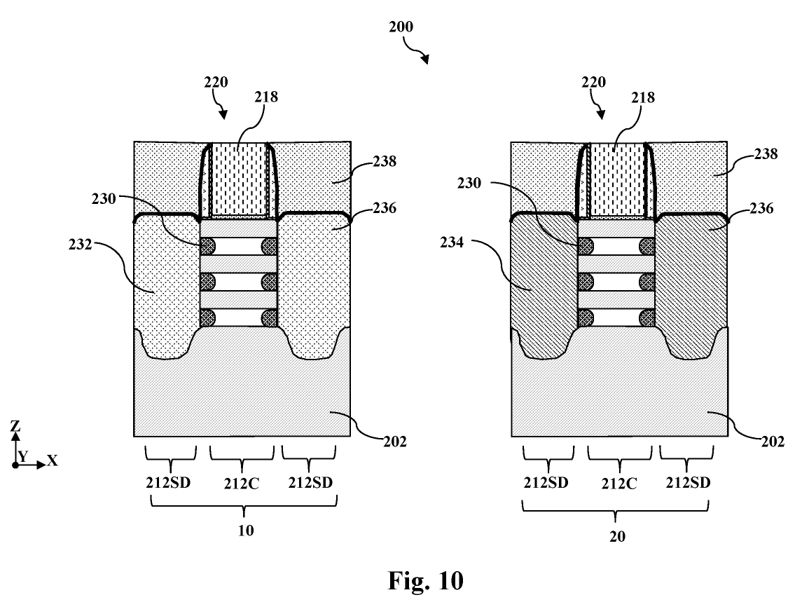

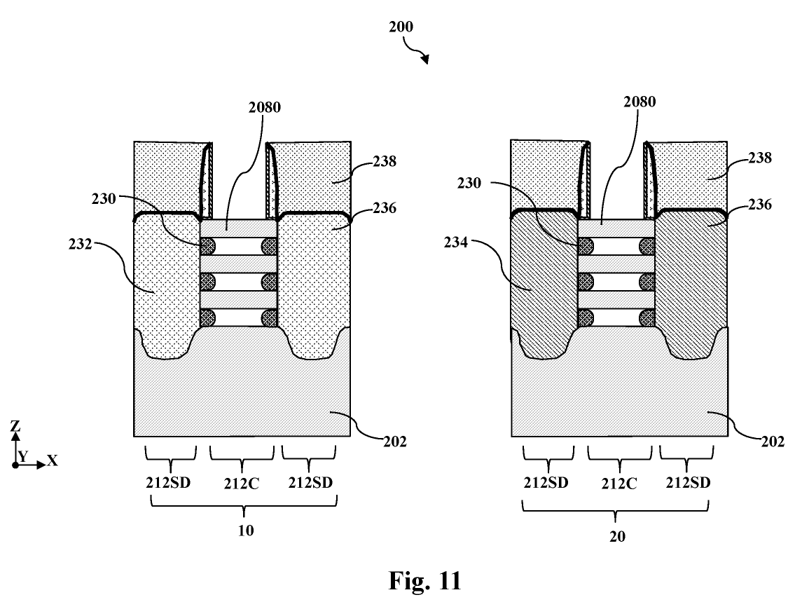

Referring to FIGS. 3-11, method 100 includes a block 102 where first nanostructures 2080 are formed between two first source/drain features 232 over a first region 10 of a substrate 202 and second nanostructures 2080 are formed between two second source/drain features 234 over a second region 20 of the substrate 202. Operations at block 102 includes formation of a stack 204 over a substrate 202 (shown in FIG. 4), patterning of the stack 204 and a portion of the substrate 202 to form a fin-shaped structure 212 (shown in FIG. 5), formation of a dummy gate stack 220 over channel regions of the fin-shaped structure 212 (shown in FIGS. 6 and 7), formation of a gate spacer layer 226 and recessing of source/drain regions 212SD of the fin-shaped structure 212 (shown in FIG. 8), formation of first source/drain features 232 and second source/drain features 234 (shown in FIG. 9), deposition of a contact etch stop layer (CESL) 236 and an interlayer dielectric (ILD) layer 238 (shown in FIG. 10), and removal of the dummy gate stack 220 and release of the first nanostructures 2080 and second nanostructures 2080 in the first region 10 and the second region 20 (shown in FIG. 11).

Referring to FIG. 4, the substrate 202 is part of a precursor structure 200 that undergoes the various operations of method 100. In some embodiments, the substrate 202 may be a semiconductor substrate such as a silicon (Si) substrate. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features. The substrate 202 may include various doping configurations depending on design requirements as is known in the art. For example, the substrate 202 may include a p-type well (i.e., a p-type dopant profile) and an n-type well (i.e., an n-type doping profile). In some implementations, the n-type dopant for forming the n-type well may include phosphorus (P) or arsenic (As) and the p-type dopant for forming the p-type well may include boron (B). The suitable doping for the n-type well or the p-type well may include ion implantation of dopants and/or diffusion processes. In the depicted embodiments, the substrate 202 includes a first region 10 and a second region 20. While the first region 10 and the second region 20 are shown in FIG. 4 as being discontinuous, it should be noted that the first region 10 and the second region 20 may be immediately adjacent to one another.

Referring still to FIG. 4, the stack 204 includes sacrificial layers 206 of a first semiconductor composition interleaved by channel layers 208 of a second semiconductor composition. The first and second semiconductor compositions may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 4, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

In some embodiments, all sacrificial layers 206 may have a substantially uniform first thickness between about 5 nm and about 20 nm and all of the channel layers 208 may have a substantially uniform second thickness between about 3 nm and about 10 nm. The first thickness and the second thickness may be identical or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes at a temperature between about 600° C and about 800° C. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1x10¹⁷ cm⁻³), where for example, no intentional doping is performed during the epitaxial growth processes for the stack 204.

Referring FIG. 5, a fin-shaped structure 212 is formed from the stack 204 and a portion of the substrate 202. To pattern the stack 204, a hard mask layer 210 (shown in FIG. 4) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shaped structure 212 may be patterned from the stack 204 and a portion of the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 5, the etch process forms trenches extending through the stack 204 and a portion of the substrate 202. The trenches define the fin-shaped structures 212, including base fins 212B formed from the substrate 202. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 5, the fin-shaped structure 212, along with the sacrificial layers 206 and the channel layers 208 therein, extends vertically along the Z direction and lengthwise along the X direction.

An isolation feature 214 is formed adjacent the fin-shaped structure 212. In some embodiments, the isolation feature 214 may be formed in the trenches to isolate the fin-shaped structures 212 from a neighboring active region, which may be another fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. As shown in FIG. 5, while the base fins 212B are disposed in or surrounded by the STI feature 214, the rest of the fin-shaped structure 212 that is formed from the stack 204 rises above the STI feature 214 after the recessing.

Reference is now made to FIGS. 6 and 7. A dummy gate stack 220 is formed over a channel region 212C of the fin-shaped structure 212. In some embodiments, a gate replacement process (or gate-last process) is adopted where the dummy gate stack 220 serves as a placeholder to undergo various processes and is to be removed and replaced by the functional gate structure. Other processes and configuration are possible. In some embodiments illustrated in FIG. 7, the dummy gate stack 220 is formed over the fin-shaped structure 212 and the fin-shaped structure 212 in the first region 10 and the second region 20 may be each divided into channel regions 212C underlying the dummy gate stacks 220 and source/drain regions 212SD that do not underlie the dummy gate stacks 220. The channel regions 212C are adjacent the source/drain regions 212SD. As shown in FIG. 7, the channel region 212C is disposed between two source/drain regions 212SD along the X direction.

The formation of the dummy gate stack 220 may include deposition of layers in the dummy gate stack 220 and patterning of these layers. Referring to FIG. 6, a dummy dielectric layer 216, a dummy electrode layer 218, and a gate-top hard mask layer 222 may be deposited over the precursor structure 200. In some embodiments, the dummy dielectric layer 216 may be formed on the fin-shaped structure 212 using a chemical vapor deposition (CVD) process, an ALD process, an oxygen plasma oxidation process, a thermal oxidation process, or other suitable processes. In some instances, the dummy dielectric layer 216 may include silicon oxide. When the dummy dielectric layer 216 is formed using an oxidation process, it may be selectively formed on exposed surfaces of the fin-shaped structure 212, as illustrated in FIG. 6. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 7. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 7, no dummy gate stack 220 is disposed over the source/drain region 212SD of the fin-shaped structure 212.

Referring now to FIG. 8, at least one gate spacer layer 226 is deposited over the dummy gate stack 220 in the first region 10 and the second region 20. In some embodiments, the at least one gate spacer layer 226 is deposited conformally over the precursor structure 200, including over top surfaces and sidewalls of the dummy gate stack 220. The term “conformally” may be used herein for ease of description of a layer having substantially uniform thickness over various regions. The at least one gate spacer layer 226 may be a single layer or a multi-layer. In the depicted embodiments, the at least one gate spacer layer 226 includes a first spacer layer 226-1 and a second spacer layer 226-2 disposed over the first spacer layer 226-1. A composition of the first spacer layer 226-1 may be different from a composition of the second spacer layer 226-2. In some implementation, a dielectric constant of the first spacer layer 226-1 is greater than a dielectric constant of the second spacer layer 226-2. The at least one gate spacer layer 226, including the first spacer layer 226-1 and the second spacer layer 226-2, may include silicon oxide, silicon carbonitride, silicon oxycarbide, silicon oxycarbonitride, or silicon nitride. The at least one gate spacer layer 226 may be deposited over the dummy gate stack 220 using processes such as, a CVD process, a subatmospheric CVD (SACVD) process, an ALD process, or other suitable process. For ease of reference, the at least one gate spacer layer 226 may also be referred to as the gate spacer layer 226 for simplicity.

Referring still to FIG. 8, source/drain regions 212SD of the fin-shaped structure 212 are recessed to form source/drain trenches 228. In some embodiments, the source/drain regions 212SD that are not covered by the dummy gate stack 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIG. 8, the source/drain regions 212SD of the fin-shaped structure 212 are recessed to expose sidewalls of the sacrificial layers 206 and the channel layers 208. In some implementations, the source/drain trenches 228 extend below the stack 204 into the substrate 202.

Referring to FIG. 9, inner spacer features 230 are formed. After the formation of the source/drain trenches 228, the sacrificial layers 206 in the channel regions 212C are selectively and partially recessed to form inner spacer recesses, while the exposed channel layers 208 are substantially unetched. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiment, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include an APM etch (e.g., ammonia hydroxide-hydrogen peroxide-water mixture). After the formation of the inner spacer recesses, an inner spacer material layer is deposited over the precursor structure 200, including in the inner spacer recesses. The inner spacer material layer may include silicon oxide, silicon nitride, silicon oxycarbide, silicon oxycarbonitride, silicon carbonitride, metal nitride, or a suitable dielectric material and may be deposited using CVD, PECVD, SACVD, ALD or other suitable methods. The deposited inner spacer material layer is then etched back to remove excess inner spacer material layer over the gate spacer layer 226 and sidewalls of the channel layers 208, thereby forming the inner spacer features 230. In some embodiments, the etch back process to form the inner spacer features 230 may be a dry etch process that includes use of an oxygen-containing gas, hydrogen (H₂), nitrogen (N₂), a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. While not explicitly shown, a cleaning process may be performed after the etch back process to remove native oxide and debris from surfaces of the channel layers 208.

Reference is still made to FIG. 9. First source/drain features 232 are formed over source/drain regions 212SD in the first region 10 and second source/drain features 234 are formed over source/drain regions 212SD in the second region 20. Each of the first source/drain features 232 and the second source/drain features 234 may be epitaxially and selectively formed from the exposed sidewalls of the channel layers 208 and exposed surfaces of the substrate 202, while sidewalls of the sacrificial layers 206 remain covered by the inner spacer features 230. Suitable epitaxial processes for formation of the first source/drain features 232 and the second source/drain features 234 include vapor-phase epitaxy (VPE), ultra-high vacuum CVD (UHV-CVD), molecular beam epitaxy (MBE), and/or other suitable processes. The epitaxial growth process may use gaseous precursors, which interact with the composition of the substrate 202 and the channel layers 208. In some embodiments, parameters of the epitaxial growth process are selected such that the first source/drain features 232 and the second source/drain features 234 are not epitaxially deposited on the inner spacer features 230. That said, the overgrowth of the first source/drain features 232 and the second source/drain features 234 may merge over some of the inner spacer feature 230.

The first source/drain features 232 and the second source/drain features 234 may have the same conductivity type and may each include more than one epitaxial layers. When the first source/drain features 232 and the second source/drain features 234 are n-type, they may include silicon (Si) doped with an n-type dopant, such as phosphorus (P) or arsenic (As). When the first source/drain features 232 and the second source/drain features 234 are p-type, they may include silicon germanium (SiGe) doped with a p-type dopant, such as boron (B). When each of the first source/drain features 232 and the second source/drain features 234 is n-type and includes multiple epitaxial layers, the epitaxial layer closer to the channel layers 208 and the substrate 202 may include lower n-type dopant concentrations and the epitaxial layer(s) away from the channel layers 208 and the substrate may include higher n-type dopant concentrations. Similarly, when each of the first source/drain features 232 and the second source/drain features 234 is p-type and includes multiple epitaxial layers, the epitaxial layer closer to the channel layers 208 and the substrate 202 may include lower p-type dopant concentrations and the epitaxial layer(s) away from the channel layers 208 and the substrate may include higher p-type dopant concentrations. Additionally, when each of the first source/drain features 232 and the second source/drain features 234 is p-type and includes multiple epitaxial layers, the epitaxial layer closer to the channel layers 208 and the substrate 202 may include lower germanium (Ge) contents and the epitaxial layer(s) away from the channel layers 208 and the substrate may include higher germanium (Ge) contents.

Referring to FIG. 10, a contact etch stop layer (CESL) 236 and an interlayer dielectric (ILD) layer 238 are deposited over the first source/drain features 232 and the second source/drain features 234. The CESL 236 may include silicon nitride, silicon oxynitride, and/or other materials known in the art. The ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the CESL 236 is first conformally deposited over the first region 10 and the second region 20 by CVD, ALD, plasma-enhanced chemical vapor deposition (PECVD) process and/or other suitable deposition or oxidation processes and the ILD layer 238 is deposited over the CESL 236 by spin-on coating, FCVD, CVD, or other suitable deposition technique. In some embodiments, after formation of the ILD layer 238, the precursor structure 200 may be annealed to improve integrity of the ILD layer 238. As shown in FIG. 10, after the deposition of the CESL 236 and the ILD layer 238, a planarization process, such as a chemical mechanical polishing (CMP) process, may be performed to remove excess materials. As shown in FIG. 10, the planarization process also exposes the dummy electrode layer 218 of the dummy gate stacks 220 in the first region 10 and the second region 20.

Reference is now made to FIG. 11. The exposed dummy gate stacks 220 are removed and sacrificial layers 206 in the channel regions 212C are selectively removed to release the first nanostructures 2080 in the first region 10 and the second nanostructures 2080 in the second region 20. The removal of the dummy gate stacks 220 may include one or more etching processes that are selective to the material in the dummy gate stacks 220. For example, the removal of the dummy gate stacks 220 may be performed using as a selective wet etch, a selective dry etch, or a combination thereof. After the removal of the dummy gate stacks 220, sidewalls of the channel layers 208 and sacrificial layers 206 in the channel regions 212C are exposed. Thereafter, the sacrificial layers 206 in the channel regions 212C are selectively removed to release the first nanostructures 2080 in the first region 10 and the second nanostructures 2080 in the second region 20. The first nanostructures 2080 in the first region 10 and the second nanostructures 2080 in the second region 20 may also be referred to as channel members 2080. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

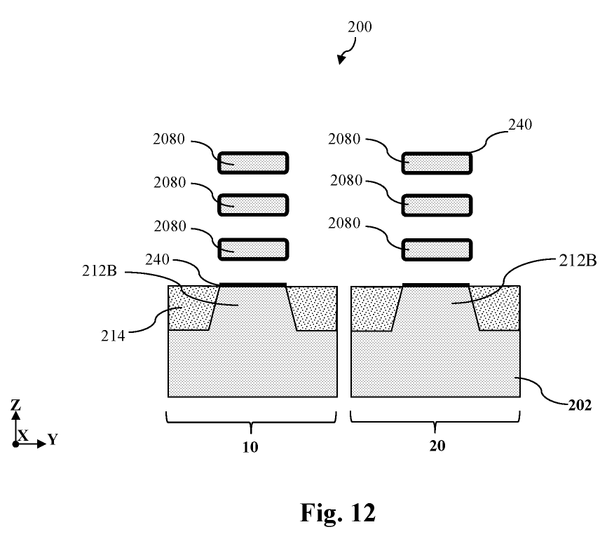

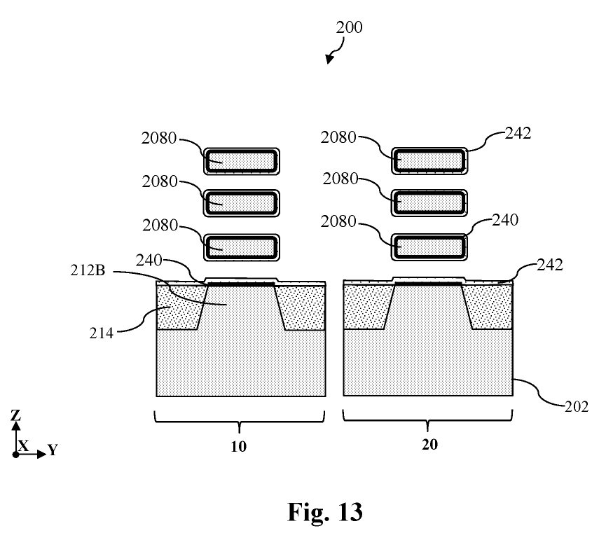

Referring to FIGS. 3 and 12, method 100 includes a block 104 where an interfacial layer 240 is formed over the first nanostructures 2080 and the second nanostructures 2080. As shown in FIG. 12, the first nanostructures 2080 are disposed over the base fin 212B in the first region 10 and the second nanostructures 2080 are disposed over the base fin 212B in the second region 20. Because the base fin 212B is patterned from the substrate 202, the base fin 212B includes the same composition with the substrate 202. The interfacial layer 240 may include silicon oxide or silicon oxynitride, or other suitable material. In some embodiments, the interfacial layer 240 may be deposited over surfaces of the first nanostructures 2080, surfaces of the second nanostructures, and top surfaces of the base fins 212B using a suitable method, such as atomic layer deposition (ALD), chemical vapor deposition (CVD), ozone oxidation, thermal oxidation, or other suitable method. The interfacial layer 240 serves the function to control and reduce gate leakage current and improve interfacial adhesion between the gate dielectric layer 242 (shown in FIG. 13) and the nanostructures (including the first nanostructures 2080 in the first region 10 and the second nanostructures 2080 in the second region 20). In the depicted embodiments, the interfacial layer 240 is formed using thermal oxidation and the interfacial layer 240 is selectively deposited on semiconductor surfaces but not on dielectric surfaces, such as the top surfaces of the isolation feature 214.

Referring to FIGS. 3 and 13, method 100 includes a block 106 where a gate dielectric layer 242 is deposited over the interfacial layer 240. In some embodiments, the gate dielectric layer 242 is high-k dielectric layer as its dielectric constant is greater than that of silicon dioxide (~3.9). In some instances, a dielectric constant of the gate dielectric layer 242 is more than twice, such as between 3 times and about 5 times, of a dielectric constant of the interfacial layer 240 or that of the isolation feature 214. In some implementations, the gate dielectric layer 242 may include doped or undoped hafnium oxide (HfO₂), doped or undoped zirconium oxide (ZrO₂), doped or undoped titanium oxide (TiO₂), or doped or undoped aluminum oxide (Al₂O₃). For example, the gate dielectric layer 242 may include hafnium silicon oxide (HfSiO), hafnium silicon oxynitride (HfSiON), or hafnium aluminum oxide (HfAlO), hafnium tantalum oxide (HfTaO), Hafnium zirconium oxide (HfZrO), zirconium silicon oxide (ZrSiO₂), hafnium titanium oxide (HfTiO), or a combination thereof. Upon conclusion of operations at block 106, each of the first nanostructures 2080 in the first region 10 and the second nanostructures 2080 in the second region 20 is wrapped around by the interfacial layer 240 and the gate dielectric layer 242. Furthermore, as illustrated in FIG. 13, the deposition of the gate dielectric layer 242 may not be selective and the gate dielectric layer 242 may be deposited over the isolation feature 214.

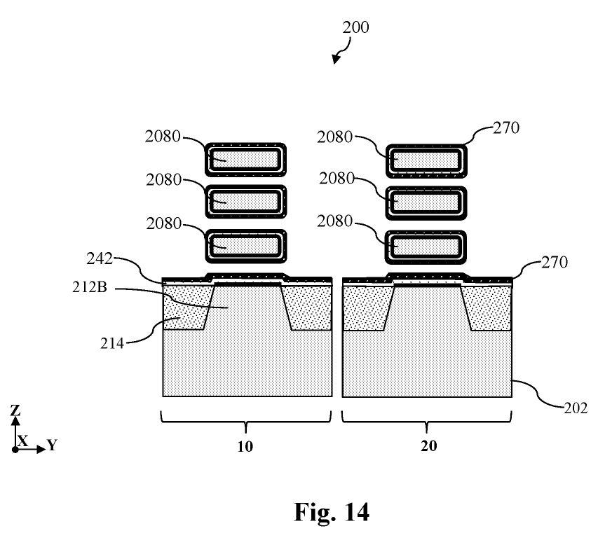

Referring to FIGS. 3 and 14, method 100 includes a block 108 where a barrier layer 270 is deposited over the gate dielectric layer 242. The barrier layer 270 may be a metal oxide that is capable of slowing down diffusion of a dipole dopant. In some embodiments, the barrier layer 270 includes aluminum oxide. The barrier layer 270 may be deposited using atomic layer deposition (ALD), chemical vapor deposition (CVD), or metalorganic chemical vapor deposition (MCCVD). As shown in FIG. 14, the barrier layer 270 is deposited to wrap around each of the first nanostructures 2080 over the first region 10 and the second nanostructures 2080 over the second region 20. The barrier layer 270 does not completely fill the space vertically between two adjacent ones of the first and second nanostructures 2080 such that the subsequently deposited dipole dopant layer 280 may wrap around each of the first and second nanostructures 2080. Stage (A) in FIG. 1 illustrates that the barrier layer 270 is deposited directly on the gate dielectric layer 242.

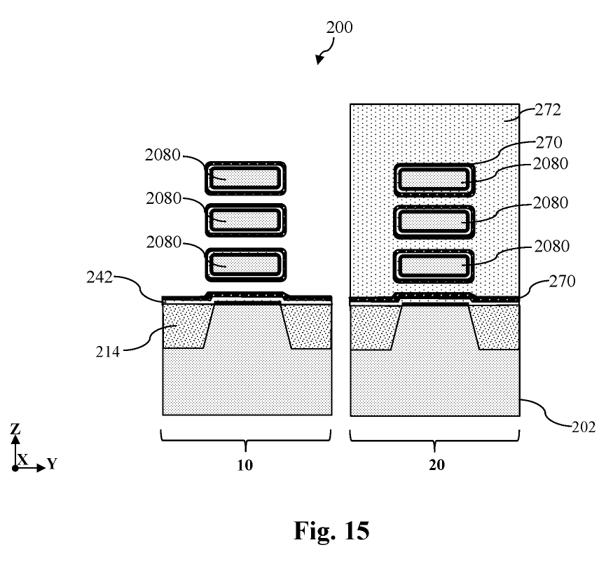

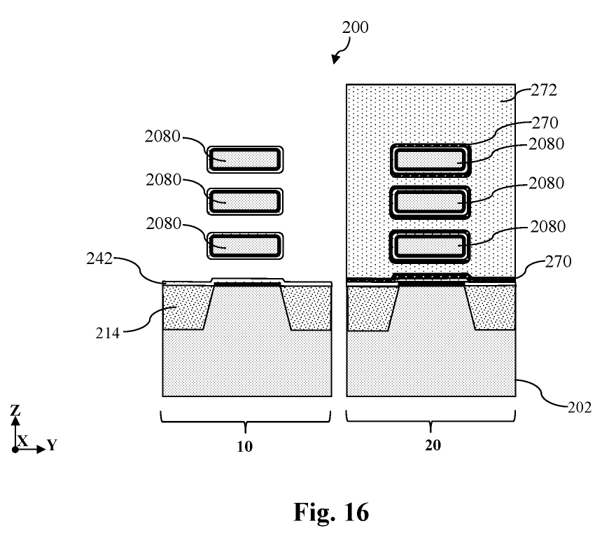

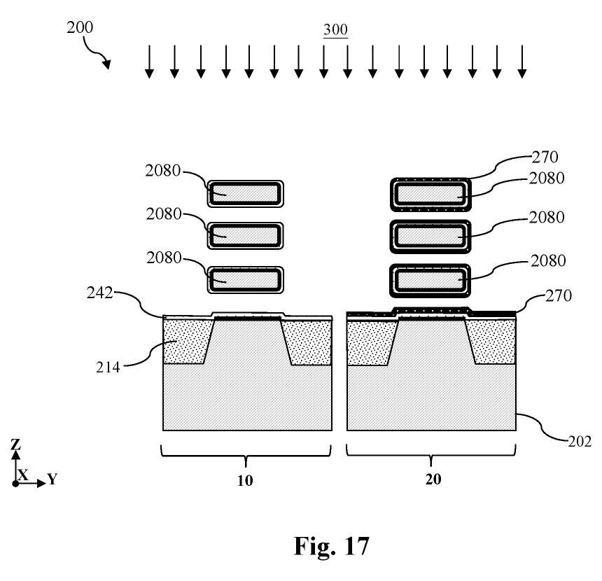

Referring to FIGS. 3 and 15-17, method 100 includes a block 110 where the barrier layer 270 over the first region 10 is selectively removed. Operations at block 110 includes forming of a mask layer 272 over the second region 20 (shown in FIG. 15), removing the barrier layer 270 over the first region 10 (shown in FIG. 16), and removing the mask layer 272 using an ashing process 300 (shown in FIG. 17). Reference is now made to FIG. 15. The mask layer 272 may include a photoresist layer, a bottom antireflective coating (BARC), or a combination thereof. In an example process, the mask layer 272 is first deposited over the precursor structure 200 using spin-on coating or flowable CVD (FCVD). Photolithography and etching processes are then performed to pattern the mask layer 272 such that the patterned mask layer 272 covers the second region 20 while the first region 10 is free from the mask layer 272. Reference is then made to FIG. 16. With the patterned mask layer 272 servicing as an etch mask, the barrier layer 270 is removed from the first region 10, including from over surfaces the gate dielectric layer 242 around the first nanostructures 2080, over the isolation feature 214 and the base fin 212B. The removal of the barrier layer 270 over the first region 10 may be achieved using a selective wet etch process. The selective wet etch process may include use of hydrogen fluoride (HF), phosphoric acid (H₃PO₄), hydrochloric acid (HCl), hydrogen peroxide (H₂O₂), sulfuric acid (H₂SO₄), or a combination thereof. Stage (B) in FIG. 1 illustrates that the barrier layer 270 is selectively from the gate dielectric layer 242 in the first region 10.

Reference is then made to FIG. 17. The ashing process 300 is performed to remove the mask layer 272 from over the second region 20. In some embodiments, the ashing process 300 may include use of plasma of nitrogen (N₂) and hydrogen (H₂). As described above in conjunction with stage (C) in FIG. 1. The ashing process 300 may introduce nitrogen to the first region 10. As illustrated in FIG. 2, it has been observed that the nitrogen may diffuse into the interfacial layer 240 in the first region 10. In some embodiments, a nitrogen concentration in the interfacial layer 240 gradually increases from an interface with a channel (below the interfacial layer 240 in FIG. 1) toward a substantially mid-depth point in the interfacial layer 240 and then gradually decreases toward an interface with the gate dielectric layer 242. The barrier layer 270 in the second region 20 blocks introduction to the second region 20. As illustrated in FIG. 2, little or no nitrogen makes its way in the interfacial layer 240 in the second region 20.

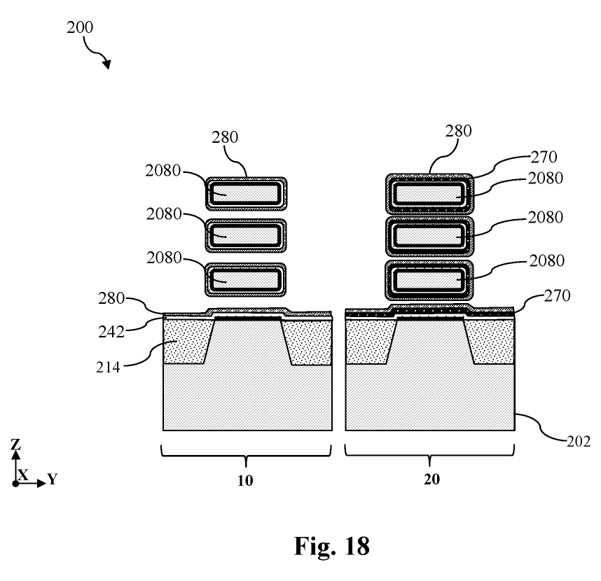

Referring to FIGS. 3 and 18, method 100 includes a block 112 where a dipole dopant layer 280 is deposited over the first nanostructures 2080 and the second nanostructures 2080. At block 112, the dipole dopant layer 280 is deposited directly on the gate dielectric layer 242 in the first region 10 and the barrier layer 270 in the second region 20. That is, over the second region 20, the dipole dopant layer 280 is spaced apart from the gate dielectric layer 242 by the barrier layer 270. As its name suggests, the dipole dopant layer 280 includes an element that can induce a dipole that can lower or raise a threshold voltage of a transistor. The dipole dopant layer 280 may include n-dipole dopant or p-dipole dopant. Example n-dipole dopants may include lanthanum (La), yttrium (Y), lutetium (Lu), strontium (Sr), erbium (Er), or magnesium (Mg). Example p-dipole dopants may include titanium (Ti) or niobium (Nb). In one embodiment, the dipole dopant layer 280 includes lanthanum oxide. At block 112, the dipole dopant layer 280 may be deposited using atomic layer deposition (ALD), chemical vapor deposition (CVD), or metalorganic chemical vapor deposition (MCCVD). Stage (D) in FIG. 1 illustrates that the dipole dopant layer 280 is deposited over the first region 10 and the second region 20.

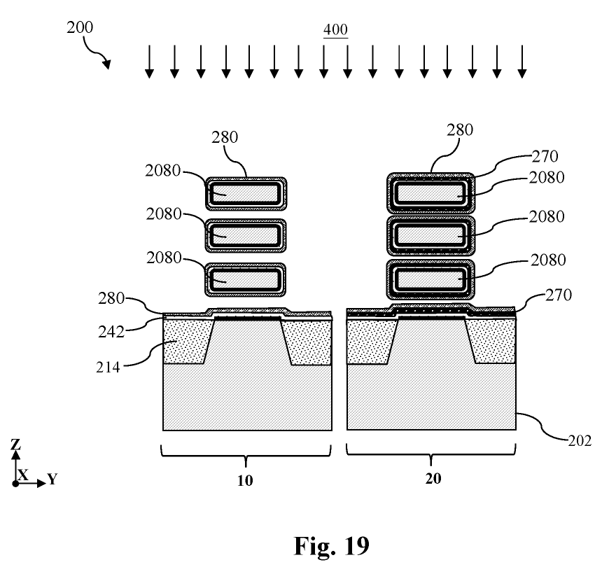

Referring to FIGS. 3 and 19, method 100 includes a block 114 where a dipole drive-in process 400 is performed. In some implementation, the dipole drive-in process 400 may be an anneal process having an anneal temperature between about 500 ℃ and about 800 ℃. The dipole drive-in process 400 not only drives a dipole dopant (D) into the gate dielectric layer 242 over the first region 10 but also drives metal dopant (M) from the barrier layer 270 into the gate dielectric layer 242 over the second region 20. As described above in conjunction with FIG. 2 above, because the barrier layer 270 only covers the second region 20 when the dipole drive-in process 400 is performed, the dopant concentration [M] in the gate dielectric layer 242 over the second region 20 is significantly higher than that over the first region 10. When the barrier layer 270 includes aluminum oxide or aluminum nitride, the metal dopant M is aluminum (Al). Because the dipole dopant layer 280 is spaced apart from the gate dielectric layer 242 over the second region 20 by the barrier layer 270, little or no dipole dopant makes its way into the gate dielectric layer 242 over the second region 20.

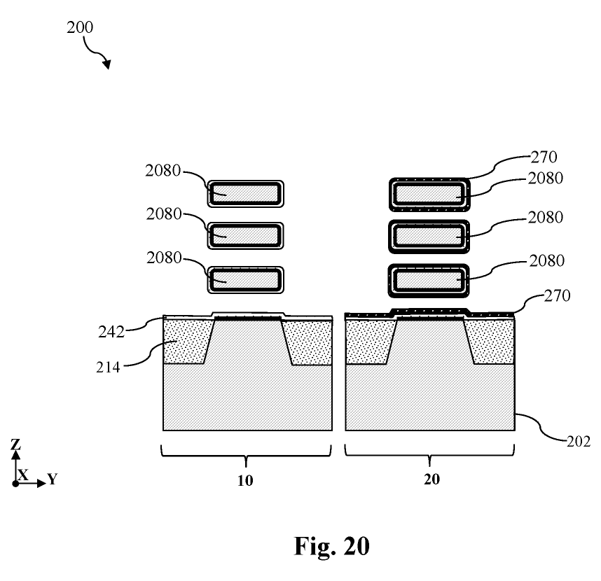

Referring to FIGS. 3 and 20, method 100 includes a block 116 where the dipole dopant layer 280 is removed from over the first region 10 and the second region 20. After the dipole drive-in process 400, the dipole dopant layer 280 is selectively removed from the precursor structure 200, exposing the gate dielectric layer 242 over the first region 10 and the barrier layer 270 over the second region 20. In some embodiments, the dipole dopant layer 280 may be removed using a wet etch. The wet etch at block 116 may include use of hydrogen chloride (HCl).

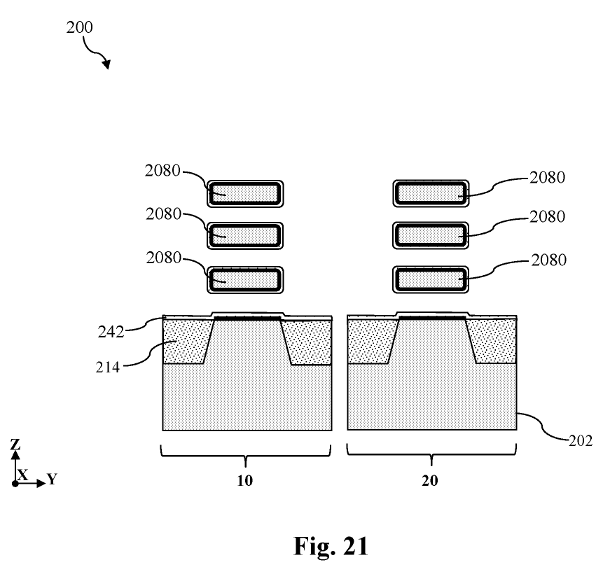

Referring to FIGS. 3 and 21, method 100 includes a block 118 where the barrier layer 270 over the second region 20 is removed. In some embodiments, the barrier layer 270 over the first region 10 may be removed using a selective wet etch process. The selective wet etch process may include use of hydrogen fluoride (HF), phosphoric acid (H₃PO₄), hydrochloric acid (HCl), hydrogen peroxide (H₂O₂), sulfuric acid (H₂SO₄), or a combination thereof. Stage (G) in FIG. 1 illustrates that the barrier layer 270 is selectively from the gate dielectric layer 242 in the second region 20.

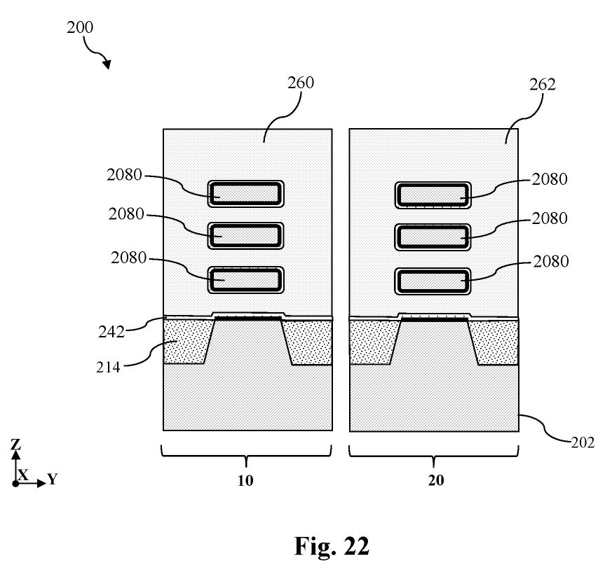

Referring to FIGS. 3 and 22, method 100 includes a block 120 where a first gate electrode 260 is formed to wrap around the first nanostructures 2080 and a second gate electrode 262 is formed to wrap around the second nanostructures 2080. In the depicted embodiments, the transistors formed over the first region 10 and the second region 20 are of the same conductivity types and have different threshold voltages. In some embodiments, the transistors formed over the first region 10 and the second region 20 are n-type transistors. In some alternative embodiments, the transistors formed of the first region 10 and the second region 20 are p-type transistors. When the transistors over the first region 10 and the second region 20 are n-type transistors, the first gate electrode 260 and the second gate electrode 262 include an n-type work function layer and a metal fill. In these embodiments, the n-type work function layer may include an aluminum-containing layer, such as titanium aluminum (TiAl), titanium aluminum carbide (TiAlC), tantalum aluminum (TaAl), tantalum aluminum carbide (TaAlC), titanium aluminum nitride (TiAlN), or a combination thereof. The metal fill layer may include tungsten (W). When the transistors over the first region 10 and the second region 20 are p-type transistors, the first gate electrode 260 and the second gate electrode 262 include a p-type work function layer, a diffusion barrier layer, an n-type work function layer, and a metal fill. In these embodiments, the p-type work function layer may include titanium nitride (TiN), titanium silicon nitride (TiSiN), tantalum nitride (TaN), tungsten carbonitride (WCN), or molybdenum (Mo). The diffusion barrier layer may include titanium aluminum carbide (TiAlC), titanium nitride (TiN), titanium nitride oxide (TiNO), hafnium oxide (HfO), or tungsten nitride (WN). The n-type work function layer may include as titanium aluminum (TiAl), titanium aluminum carbide (TiAlC), tantalum aluminum (TaAl), tantalum aluminum carbide (TaAlC), titanium aluminum nitride (TiAlN), or a combination thereof. The metal fill layer may include tungsten (W). Because at least one of the n-type work function layer and the p-type work function layer includes the element titanium, it can be said that the first gate electrode 260 and the second gate electrode 262 include a titanium-based material. For ease of reference, the first gate electrode 260, the gate dielectric layer 242 and the interfacial layer 240 may be referred to as a first gate structure and the second gate electrode 262, the gate dielectric layer 242 and the interfacial layer 240 may be referred to as a second gate structure.

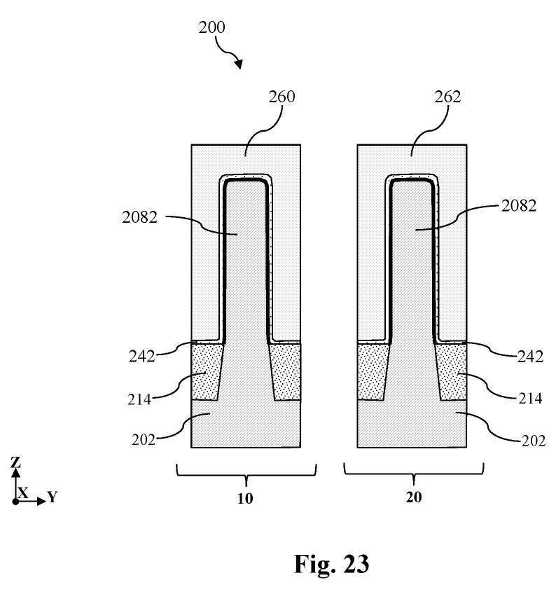

It should be appreciated that method 100 in FIG. 3 may also be implemented to form other types of multi-gate devices. For example, method 100 may be applied to form FinFETs or complementary field effect transistors (CFETs) having different threshold voltages. FIG. 23 illustrates FinFETs formed over the first region 10 and the second region 20. Instead of the first nanostructures 2080 and the second nanostructures 2080 shown in FIG. 22, the FinFETs in FIG. 23 includes fin structures 2082 over the first region 10 and the second region 20. Because the interfacial layer 240 and the gate dielectric layer 242 in FIG. 23 undergo the dipole doping process described above in conjunction with FIGS. 1-22, the interfacial layer 240 in the first region 10 includes nitrogen, the gate dielectric layer 242 in the first region 10 includes the dipole dopant, and the gate dielectric layer 242 in the second region 20 includes the metal dopant from the barrier layer 270.

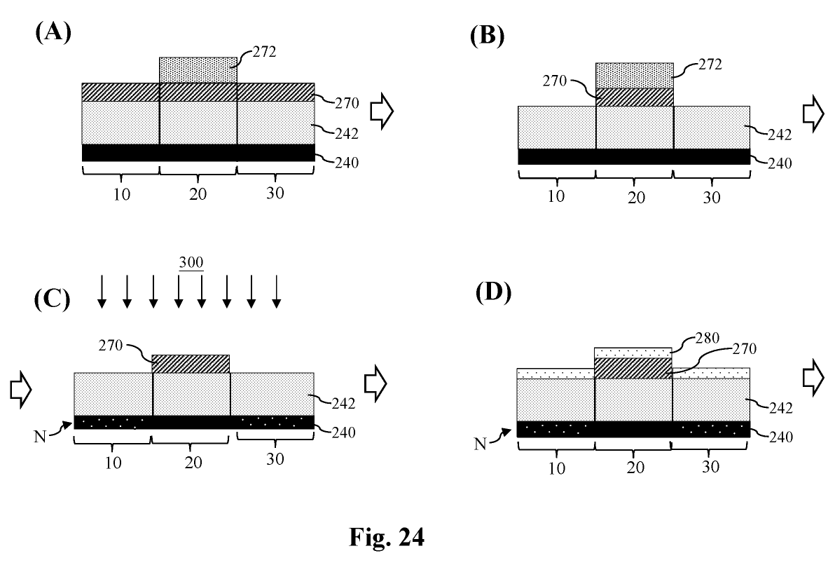

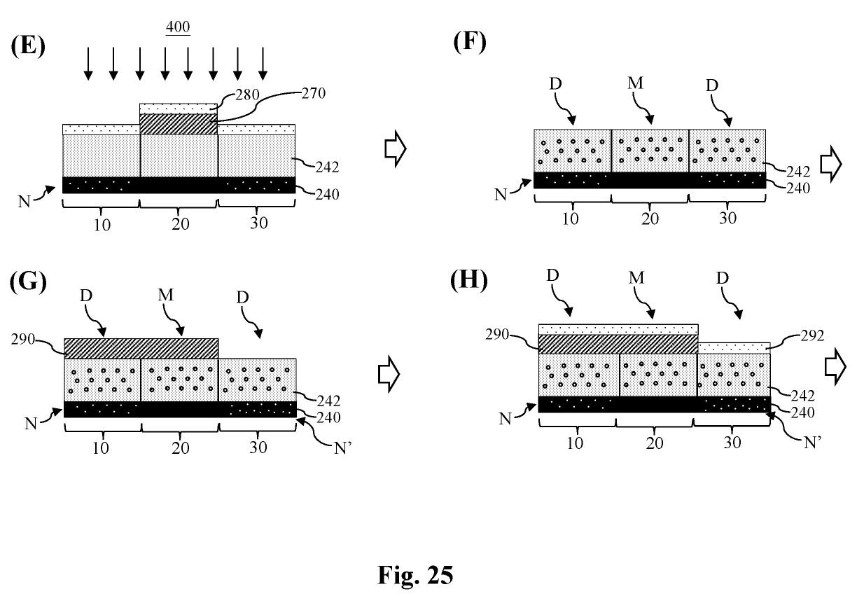

The schematic flow in FIG. 1 and method 100 in FIG. 3 describe implementing different dipole doping to two regions to achieve multi-gate transistors having different threshold voltages. FIGS. 24-26 illustrate a schematic flow to implement different dipole doping to three regions – a first region 10, a second region 20, and a third region 30. At stage (A) in FIG. 24, the barrier layer 270 is deposited over the gate dielectric layer 242 in the first region 10, the second region 20, and the third region 30. A patterned mask layer 272 is disposed over the barrier layer 270 in the second region 20. With the patterned mask layer 272 as an etch mask, the barrier layer 270 over the first region 10 and the third region 30 is etched away to expose the gate dielectric layer 242, as shown in stage (B) in FIG. 24. At stage (C), the ashing process 300 is performed to remove the patterned mask layer 272. The ashing process 300 introduces nitrogen into the interfacial layer 240 in the first region 10 and the third region 30. At stage (D), the dipole dopant layer 280 is deposited over the first region 10, the second region 20, and the third region 30. In the second region 20, the gate dielectric layer 242 is spaced apart from the dipole dopant layer 280 by the barrier layer 270. A dipole drive-in process 400 is performed, as shown in stage (E) in FIG. 25. After the dipole drive-in process 400, the barrier layer 270 and the dipole dopant layer 280 are removed at stage (F) in FIG. 25. The dipole drive-in process 400 drives in the dipole dopant (D) in the dipole dopant layer 280 in the gate dielectric layer 242 in the first region 10 and the third region 30. Additionally, the dipole drive-in process 400 drives the metal dopant (M) in the barrier layer 270 in the gate dielectric layer 242 in the second region 20. At stage (G), another barrier layer 290 is deposited and patterned to cover the first region 10 and the second region 20. For ease of reference, the barrier layer 270 may be referred to as the first barrier layer 270 and the another barrier layer 290 may be referred to as the second barrier layer 290. While not explicitly shown in FIG. 25, an ashing process 300 is performed to remove a mask layer over the second barrier layer 290. This operation further increases the nitrogen concentration in the interfacial layer 240 in the third region 30. At stage (H), another dipole dopant layer 292 is deposited over the first region 10, the second region 20, and the third region 30. For ease of reference, the dipole dopant layer 280 may be referred to as the first dipole dopant layer 280 and the another dipole dopant layer 292 may be referred to as the second dipole dopant layer 292. Over the first region 10 and the second region 20, the second dipole dopant layer 292 is spaced apart from the gate dielectric layer 242 by the second barrier layer 290.

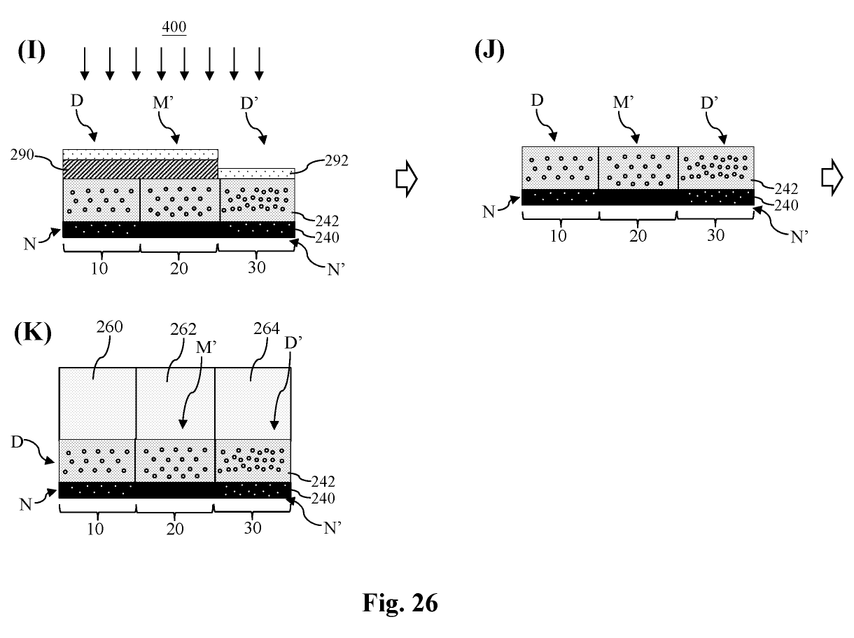

Reference is now made to FIG. 26. At stage (I), the dipole drive-in process 400 is performed again. The dipole drive-in process 400 further increases the dipole dopant concentration (D) in the gate dielectric layer 242 in the third region 30 to an increased dipole dopant concentration (D’). It also increases the metal dopant concentration (M) in the gate dielectric layer 242 in the second region 20 to an increased metal dopant concentration (M’). At stage (J) in FIG. 26, the second dipole dopant layer 292 and the second barrier layer 290 are sequentially removed, as illustrated in stage (J) in FIG. 26. At stage (K), a first gate electrode 260, a second gate electrode 262 and a third gate electrode 264 are formed over the first region 10, the second region 20, and the third region 30, respectively. In some embodiments, the first gate electrode 260, the second gate electrode 262 and the third gate electrode 264 may have similar compositions. Due to the different dipole dopant concentrations, and different metal dopant concentrations, and the different nitrogen concentrations, the as-formed transistors have different threshold voltages.

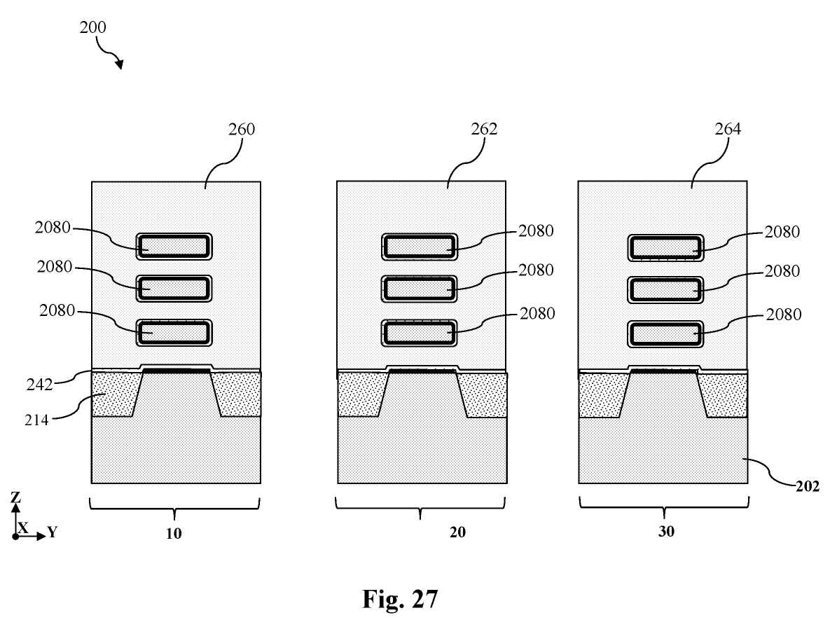

When the doping scheme shown in FIGS. 24-26 is adopted, GAA transistors having different threshold voltages may be formed in the first region 10, the second region 20, and the third region 30, as illustrated in FIG. 27. It should be noted that the nanostructures 2080 shown in FIG. 27 extend between source/drain features similar to the first source/drain features 232 and the second source/drain features 234 shown in FIGS. 10 and 11. According to the present disclosure, the implementation of the barrier layer 270 during dipole drive-in helps overcome the p-type work function roll-off and undesirable intermixing of the gate dielectric layer and the dipole dopant layer. The disclosed process also helps combat threshold voltage variations (i.e., Sigma) among pass-gate transistors and pull-down transistors in static random access memory (SRAM) applications. In SRAM technology, pass-gate transistors are used for reading and writing data and pull-down transistors maintain the state of the cell. Variations in threshold voltages of these pass-gate and pull-down transistors may lead to high gate leakage current or high standby current, impacting yield. Processes and structures of the present disclosure may reduce the threshold voltage variations.

The present disclosure provides embodiments of processes for forming a gate structure of a multi-gate device. In one embodiment, a method is provided. The method includes forming a first channel member over a first region of a substrate and a second channel member over a second region of the substrate, forming an interfacial layer over the first channel member and the second channel member, forming a gate dielectric layer over the interfacial layer, selectively depositing a barrier layer over the gate dielectric layer over the second region, after the selectively depositing, depositing a dipole dopant layer over the gate dielectric layer over the first region and the barrier layer over the second region, performing a dipole drive-in process, after the performing of the dipole drive-in process, removing the dipole dopant layer from the gate dielectric layer over the first region and the barrier layer over the second region, after the removing of the dipole dopant layer, removing the barrier layer from the second region, and forming a gate electrode over the first region and the second region. The gate electrode include a titanium-based material.

In some embodiments, the barrier layer includes aluminum oxide. In some embodiments, the dipole dopant layer includes lanthanum oxide. In some embodiments, the performing of the dipole drive-in process causes diffusion of an element in the dipole dopant layer into the gate dielectric layer in the first region as well as diffusion of an element in the barrier layer into the gate dielectric layer in the second region. In some embodiments, the element in the dipole dopant layer includes lanthanum (La), yttrium (Y), lutetium (Lu), strontium (Sr), erbium (Er), or magnesium (Mg). The element in the barrier layer includes aluminum (Al). In some embodiments, the dipole drive-in process includes a process temperature between about 500 ℃ and about 800 ℃. In some embodiments, the selectively depositing the barrier layer includes depositing a global barrier layer over the gate dielectric layer over the first region and the second region, forming a mask layer over the global barrier layer over the second region, removing the mask layer over the first region, etching the barrier layer over the first region while the barrier layer in the second region is covered by the mask layer, and after the etching, selectively removing the mask layer over the second region. In some embodiments, the selectively removing includes use of an ashing process. The ashing process includes use of hydrogen (H₂) and nitrogen (N₂). In some embodiments, the ashing process causes nitrogen to diffuse into the interfacial layer over the first region.

In another embodiment, a method is provided. The method includes providing a structure that includes first nanostructures extending between a first pair of source/drain features, and second nanostructures extending between a second pair of source/drain features, forming an interfacial layer over the first nanostructures and the second nanostructures, depositing a gate dielectric layer over the first nanostructures and the second nanostructures, depositing a barrier layer over the gate dielectric layer over the first nanostructures and the second nanostructures, selectively removing the barrier layer from over the gate dielectric layer over the first nanostructures, after the selectively removing, depositing a dipole dopant layer over the gate dielectric layer over the first nanostructures and the barrier layer over the second nanostructures such that the dipole dopant layer is spaced apart from the second nanostructures by the barrier layer, after the depositing of the dipole dopant layer, performing a dipole drive-in process, after the performing, removing the dipole dopant layer, after the removing of the dipole dopant layer, removing the barrier layer from over the second nanostructures, and after the removing of the barrier layer, forming a gate electrode to wrap around each of the first nanostructures and each of the second nanostructures. A dielectric constant of the gate dielectric layer is greater than a dielectric constant of the interfacial layer.

In some embodiments, the performing of the dipole drive-in process causes diffusion of an element in the dipole dopant layer into the gate dielectric layer over the first nanostructures as well as diffusion of an element in the barrier layer into the gate dielectric layer over the first nanostructures. In some implementations, the element in the dipole dopant layer includes lanthanum (La), yttrium (Y), lutetium (Lu), strontium (Sr), erbium (Er), or magnesium (Mg) and the element in the barrier layer includes aluminum (Al). In some implementations, the barrier layer includes aluminum oxide. In some instances, the dipole dopant layer includes lanthanum oxide. In some embodiments, the selectively removing of the barrier layer includes use of an ashing process, and the ashing process includes use of hydrogen (H2) and nitrogen (N2).

In a further embodiment, a semiconductor structure is provided. The semiconductor structure includes a first base fin and a second base fin, an isolation feature disposed between the first base fin and the second base fin, first nanostructures stacked one over another over the first base fin, second nanostructures stacked one over another over the second base fin, a first interfacial layer wrapping around each of the first nanostructures, a second interfacial layer wrapping around the second nanostructures, a first gate dielectric layer over the first interfacial layer, a second gate dielectric layer over the second interfacial layer, and a gate electrode over the first gate dielectric layer and the second gate dielectric layer. A nitrogen content in the first interfacial layer is greater than a nitrogen content in the second interfacial layer and an aluminum content in the second gate dielectric layer is greater than an aluminum content in the first gate dielectric layer. The gate electrode includes a titanium-based material.

In some embodiments, the first gate dielectric layer and the second gate dielectric layer include a dipole inducing element. A concentration of the dipole inducing element in the first gate dielectric layer is greater than a concentration of the dipole inducing element in the second gate dielectric layer. In some implementations, the dipole inducing element includes lanthanum (La), yttrium (Y), lutetium (Lu), strontium (Sr), erbium (Er), or magnesium (Mg). In some embodiments, the first interfacial layer interfaces a top surface of the first base fin. In some embodiments, the gate electrode includes a titanium-based material.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
forming a first channel member over a first region of a substrate and a second channel member over a second region of the substrate;
forming an interfacial layer over the first channel member and the second channel member;
forming a gate dielectric layer over the interfacial layer;
selectively depositing a barrier layer over the gate dielectric layer over the second region;
after the selectively depositing, depositing a dipole dopant layer over the gate dielectric layer over the first region and the barrier layer over the second region;
performing a dipole drive-in process;
after the performing of the dipole drive-in process, removing the dipole dopant layer from the gate dielectric layer over the first region and the barrier layer over the second region;
after the removing of the dipole dopant layer, removing the barrier layer from the second region; and
forming a gate electrode over the first region and the second region,
wherein the gate electrode comprise a titanium-based material.

2. The method of claim 1, wherein the barrier layer comprises aluminum oxide.

3. The method of claim 1, wherein the dipole dopant layer comprises lanthanum oxide.

4. The method of claim 1, wherein the performing of the dipole drive-in process causes diffusion of an element in the dipole dopant layer into the gate dielectric layer in the first region as well as diffusion of an element in the barrier layer into the gate dielectric layer in the second region.

5. The method of claim 4,
wherein the element in the dipole dopant layer comprises lanthanum (La), yttrium (Y), lutetium (Lu), strontium (Sr), erbium (Er), or magnesium (Mg),
wherein the element in the barrier layer comprises aluminum (Al).

6. The method of claim 1, wherein the dipole drive-in process comprises a process temperature between about 500 ℃ and about 800 ℃.

7. The method of claim 1, wherein the selectively depositing the barrier layer comprises:
depositing a global barrier layer over the gate dielectric layer over the first region and the second region;
forming a mask layer over the global barrier layer over the second region;
removing the mask layer over the first region;
etching the barrier layer over the first region while the barrier layer in the second region is covered by the mask layer; and
after the etching, selectively removing the mask layer over the second region.

8. The method of claim 7,
wherein the selectively removing comprises use of an ashing process,
wherein the ashing process comprises use of hydrogen (H₂) and nitrogen (N₂8).

9. The method of claim 8, wherein the ashing process causes nitrogen to diffuse into the interfacial layer over the first region.

10. A method, comprising:
providing a structure comprising:
first nanostructures extending between a first pair of source/drain features, and
second nanostructures extending between a second pair of source/drain features;
forming an interfacial layer over the first nanostructures and the second nanostructures;
depositing a gate dielectric layer over the first nanostructures and the second nanostructures;
depositing a barrier layer over the gate dielectric layer over the first nanostructures and the second nanostructures;
selectively removing the barrier layer from over the gate dielectric layer over the first nanostructures;
after the selectively removing, depositing a dipole dopant layer over the gate dielectric layer over the first nanostructures and the barrier layer over the second nanostructures such that the dipole dopant layer is spaced apart from the second nanostructures by the barrier layer;
after the depositing of the dipole dopant layer, performing a dipole drive-in process;
after the performing, removing the dipole dopant layer;
after the removing of the dipole dopant layer, removing the barrier layer from over the second nanostructures; and
after the removing of the barrier layer, forming a gate electrode to wrap around each of the first nanostructures and each of the second nanostructures,
wherein a dielectric constant of the gate dielectric layer is greater than a dielectric constant of the interfacial layer.

11. The method of claim 10, wherein the performing of the dipole drive-in process causes diffusion of an element in the dipole dopant layer into the gate dielectric layer over the first nanostructures as well as diffusion of an element in the barrier layer into the gate dielectric layer over the first nanostructures.

12. The method of claim 11,
wherein the element in the dipole dopant layer comprises lanthanum (La), yttrium (Y), lutetium (Lu), strontium (Sr), erbium (Er), or magnesium (Mg),
wherein the element in the barrier layer comprises aluminum (Al).

13. The method of claim 10, wherein the barrier layer comprises aluminum oxide.

14. The method of claim 10, wherein the dipole dopant layer comprises lanthanum oxide.

15. The method of claim 10,
wherein the selectively removing of the barrier layer comprises use of an ashing process,
wherein the ashing process comprises use of hydrogen (H₂) and nitrogen (N₂15).

16. A semiconductor structure, comprising:
a first base fin and a second base fin;
an isolation feature disposed between the first base fin and the second base fin;
first nanostructures stacked one over another over the first base fin;
second nanostructures stacked one over another over the second base fin;
a first interfacial layer wrapping around each of the first nanostructures;
a second interfacial layer wrapping around the second nanostructures;
a first gate dielectric layer over the first interfacial layer;
a second gate dielectric layer over the second interfacial layer; and
a gate electrode over the first gate dielectric layer and the second gate dielectric layer,
wherein a nitrogen content in the first interfacial layer is greater than a nitrogen content in the second interfacial layer,
wherein an aluminum content in the second gate dielectric layer is greater than an aluminum content in the first gate dielectric layer,
wherein the gate electrode comprises a titanium-based material.

17. The semiconductor structure of claim 16,
wherein the first gate dielectric layer and the second gate dielectric layer comprise a dipole inducing element,
wherein a concentration of the dipole inducing element in the first gate dielectric layer is greater than a concentration of the dipole inducing element in the second gate dielectric layer.

18. The semiconductor structure of claim 17, wherein the dipole inducing element comprises lanthanum (La), yttrium (Y), lutetium (Lu), strontium (Sr), erbium (Er), or magnesium (Mg).

19. The semiconductor structure of claim 16, wherein the first interfacial layer interfaces a top surface of the first base fin.

20. The semiconductor structure of claim 16, wherein the gate electrode comprises a titanium-based material.
